(19) United States
(12) Patent Application Publication
(10) Pub. No.: US 2025/0132537 A1
(43) Pub. Date: Apr. 24, 2025

(54) OPTOELECTRONIC LIGHTING DEVICE AND PRODUCTION METHOD

(71) Applicant: ams-OSRAM International GmbH, Regensburg (DE)

(72) Inventors: Jan SEIDENFADEN, Neumarkt i.d Oberpfalz (DE); Joerg Erich SORG, Regensburg (DE); Markus HORN, Ergoldsbach (DE)

(73) Assignee: ams-OSRAM International GmbH, Regensburg (DE)

(21) Appl. No.: 18/690,295

(22) PCT Filed: Sep. 7, 2022
(86) PCT No.: PCT/EP2022/074924

§ 371 Date: Mar. 8, 2024

(30) Foreign Application Priority Data
Sep. 10, 2021 (DE) 10 2021 123 531.6

(51) Int. Cl. H01S 5/02234; H01S 5/02253; H01S 5/02255

(52) U.S. Cl. CPC H01S 5/02234; H01S 5/02253; H01S 5/02255

(57) ABSTRACT

The invention relates to an optoelectronic lighting device comprising a carrier, at least one light emitting semiconductor element which is arranged on a top surface of the carrier and is configured to emit light with a wavelength smaller than 550 nm, a mold compound which is substantially transparent to the light emitted by the semiconductor element and encapsulates the light emitting semiconductor element on the carrier, a frame which is arranged on the top surface of the carrier and projects beyond the light emitting semiconductor element in a direction perpendicular to the top surface of the carrier, and which delimits the mold compound in at least one spatial direction, and a cover element which is substantially transparent to the light emitted by the semiconductor element and which is arranged floating on the mold compound as seen in an emission direction of the optoelectronic lighting device.

### CROSS-REFERENCE TO RELATED APPLICATIONS

The present application is a national stage entry from International Application No. PCT/EP2022/074924, filed on Sep. 7, 2022, published as International Publication No. WO 2023/036851 A2 on Mar. 16, 2023, and claims the priority of German patent application No. 10 2021 123 531.6 dated Sep. 10, 2021, the disclosures of all of which are hereby incorporated by reference in their entireties into the present application.

### FIELD

The present invention relates to an optoelectronic lighting device and to a method for manufacturing an optoelectronic lighting device.

### BACKGROUND

To improve the ageing behavior, conventional laser packages, in particular laser packages for the emission of blue and/or ultraviolet light, require a hermetically sealed housing with an optical window. One of the reasons for this is that laser diodes, and in particular laser diodes for the emission of blue and/or ultraviolet light, degrade in contact with oxygen and their performance therefore decreases over time.

The optical window in such a hermetically sealed laser package should have no or as little influence as possible on the optical properties and beam quality of the light emitted by a laser diode arranged inside the hermetically sealed housing. In particular, the M² value and the optical coherence of the laser diode should not be affected by the optical window, or should be affected as little as possible.

Such laser packages with a hermetically sealed housing and a corresponding optical window, which has little or no effect on the optical properties/beam quality of the light emitted by a laser diode located inside the hermetically sealed housing, usually contain expensive materials and require complicated and expensive manufacturing processes to produce.

There is therefore a need to counteract at least one of the aforementioned problems and to specify an improved optoelectronic lighting device and a method for its manufacture.

### SUMMARY OF THE INVENTION

This and other needs are met by an optoelectronic lighting device with the features of claim 1 and a method for manufacturing an optoelectronic lighting device with the features of claim 17. Embodiments and further developments of the invention are described in the dependent claims.

An optoelectronic lighting device according to the invention comprises a carrier and at least one light emitting semiconductor element arranged on a top surface of the carrier, which is configured to emit light with a wavelength smaller than 550 nm, and in particular with a wavelength in the range between 250 nm and 550 nm. For example, the light emitting semiconductor element can be configured to emit short-wave laser light in the blue and/or ultraviolet range.

The optoelectronic lighting device further comprises a mold compound which is substantially transparent to the light emitted by the semiconductor element and which encapsulates the light emitting semiconductor element on the carrier, and a frame which is arranged on the top surface of the carrier, which projects beyond the light emitting semiconductor element in a direction perpendicular to the top surface of the carrier, and which delimits the mold compound in at least one spatial direction. In addition, a cover element which is substantially transparent to the light emitted by the semiconductor element is arranged flying or floating on the mold compound as seen in an emission direction of the optoelectronic lighting device.

By encapsulating the light emitting semiconductor element in the mold compound, the semiconductor element is in direct contact with the mold compound, but not in contact with an environment or oxygen surrounding the optoelectronic lighting device. As a result, the ageing behavior of the semiconductor element can be improved without the semiconductor element having to be encapsulated in a hermetically sealed housing.

However, encapsulating the light emitting semiconductor element in the mold compound can result in an uneven surface on a light exit surface of the light emitted by the semiconductor element from the mold compound, which can have a negative effect on the optical properties/beam quality of the light emitted by the semiconductor element. For this reason, a cover element that is substantially transparent to the light emitted by the semiconductor element is arranged on the mold compound, at least in the area of the light emission surface on the mold compound as viewed in an emission direction of the optoelectronic lighting device. The cover element is arranged and configured in such a way that the optical properties/the beam quality of the light emitted by the semiconductor element are not or only barely influenced and is arranged on the mold material with a minimum size of the beam diameter. Contrary to an uneven surface on the mold material, the cover element forms a defined plane that does not influence the phase front of the laser.

By appropriately selecting the two materials for the mold compound and the cover element, it is possible for the light emitted by the semiconductor element to propagate through the materials with n>1.

In some embodiments, the cover element is formed by an optical element, in particular a glass plate, which preserves the wavefront for the light emitted by the semiconductor element. Wavefront-preserving can be understood to mean that as little as possible of the beam quality of the light emitted by the semiconductor element is lost at the optical interfaces between the mold compound and the cover element, and between the cover element and the surroundings.

This can be achieved, for example, by the mold compound and the cover element having an substantially identical refractive index, particularly in the region of an optical interface between the mold compound and the cover element, the refractive indices of the mold compound and the cover element are matched at least in the region of the optical interface between the mold compound and the cover element. This makes it possible for the optical interface between the mold compound and the cover element to become substantially “invisible”.

Another option is to provide a high optical quality on the light entry and light exit side of the cover element and the mold compound. This can be achieved, for example, through high planarity and high surface evenness, for example in the range of λ/10 to λ/25.

The proposed optoelectronic lighting device has the advantage that no hermetically sealed housing is required to improve the aging behavior. This results in advantages such as a more flexible design of the optoelectronic lighting device, a possible miniaturization and/or integration of the optoelectronic lighting device, simpler processes in the manufacture of an optoelectronic lighting device and associated lower costs for the optoelectronic lighting device. Encapsulating the light emitting semiconductor element in the mold compound also results in a simplified sealing process for the semiconductor element and the optical interfaces within the optoelectronic lighting device are reduced.

Viewed in the direction of emission of the optoelectronic lighting device, the cover element is arranged floating on the mold compound. In this context, “floating” can be understood to mean that the cover element is substantially only connected to the mold compound and, in particular, not to the frame. For example, the cover element cannot be held by any other component of the optoelectronic lighting device and in particular not by the frame. Such an arrangement has the advantage that heating of the semiconductor element, associated heating of the mold compound surrounding the semiconductor element and, in turn, associated thermal expansion of the mold compound do not lead to detachment of the cover element. If, on the other hand, the cover element were additionally connected to the frame, heating and the associated thermal expansion of the mold compound could lead to the cover element detaching at least from the frame. In some embodiments, the cover element accordingly has no direct connection at least to the frame.

In some embodiments, the light emitting semiconductor element is formed by a side-emitting laser diode. In particular, the semiconductor element is in the form of a side-emitting laser diode and has a light emission region on one of the lateral outer surfaces of the laser diode, through which the laser diode emits light in the form of a light cone in the direction of a main emission direction.

In some embodiments, the optoelectronic lighting device additionally comprises a reflector or a prism, wherein the reflector or the prism is configured to deflect the light emitted by the semiconductor element. In particular, the reflector or the prism can be arranged downstream of the semiconductor element in the main emission direction of the semiconductor element and on the top surface of the carrier.

In some embodiments, the emission direction of the optoelectronic light emitting device is substantially perpendicular to a main emission direction of the semiconductor element. For example, the light emitted from the semiconductor element in the main emission direction can be deflected by the reflector or the prism by approximately 90° so that the emission direction of the optoelectronic light emitting device is substantially perpendicular to the main emission direction of the semiconductor element.

In some embodiments, however, the emission direction of the optoelectronic light emitting device and a main emission direction of the semiconductor element are substantially parallel. In such a case, the optoelectronic light emitting device may, for example, be designed as a side-emitting light emitting device and have a light emission area on one of the lateral outer surfaces of the light emitting device, through which the light emitting device emits light in the form of a light cone in the direction of the emission direction.

In some embodiments, the frame forms a cavity in which the light emitting semiconductor element and optionally the reflector or the prism are arranged. The cavity is at least filled with the mold compound.

However, the mold compound can also protrude beyond the frame and be arranged at least partially on an upper edge of the frame.

In some embodiments, the cover element completely covers the cavity as seen in plan view, and in particular at least partially covers an upper edge of the frame. Accordingly, the cover element may have a projected area when viewed in plan view that is at least larger than a projected area of the cavity or the area enclosed by the frame. For example, the cover element can have a projected area, seen in plan view, which substantially corresponds to the size of a projected area of an outer edge of the frame.

In some embodiments, a portion of the mold compound is disposed between the upper edge of the frame and the cover element covering this portion of the frame. In particular, in the event that the cover element has a projected area, seen in plan view, which is larger than a projected area of the cavity, a part of the mold compound can be arranged between the upper edge of the frame and the part of the cover element covering the frame. This ensures that the cover element floats on the mold compound.

In some embodiments, the cover element has a smaller surface area when viewed from above than the surface area enclosed by the frame or than the projected surface area of the cavity when viewed from above. In particular, the frame remains uncovered by the cover element when viewed from above.

In some embodiments, at least some areas of the mold compound that lie outside a light cone emitted by the optoelectronic light emitting device remain uncovered by the cover element. In other words, the cover element may be dimensioned and arranged on the mold compound such that it substantially only covers the area of the mold compound within a light cone emitted by the optoelectronic light emitting device.

In some embodiments, the mold compound is selected from the group of silicones or siloxanes. In particular, the mold compound is characterized in that it substantially does not absorb light with a wavelength smaller than 550 nm, and in particular with a wavelength in the range between 250 nm and 550 nm, or hardly absorbs it at all. The first mold compound also exhibits, for example, high temperature resistance, high resistance to high-energy light, adhesive properties and elastic properties in order to compensate for stresses due to thermal expansion.

In some embodiments, the material of the cover element is selected from the group of epoxies or glasses. In particular, the material of the cover element is characterized by the fact that it substantially does not absorb light with a wavelength smaller than 550 nm, and in particular with a wavelength in the range between 250 nm and 550 nm, or only hardly absorbs it. The second mold compound can also be characterized, for example, by low stickiness, particularly of the outer surfaces of the second mold compound, low sensitivity to particles, ease of cleaning and high rigidity in order to provide a stable outer surface.

In some embodiments, the cover element is formed by a lens or another element that shapes the beam. This can result in beam shaping or light scattering of the light emitted by the lighting device.

In some embodiments, the optoelectronic lighting device has electrical contact surfaces on a side facing away from the top of the carrier and can thus be surface-mounted.

A method according to the invention for manufacturing at least one optoelectronic lighting device, in particular an optoelectronic lighting device according to some of the aspects mentioned, comprises the steps of:
Arranging at least one light emitting semiconductor element, which is configured to emit light with a wavelength smaller than 550 nm, on a top surface of a carrier;
Arranging a frame on the top surface of the carrier, wherein the frame together with the carrier forms at least one cavity in which the at least one light emitting semiconductor element is arranged;
Molding the at least one semiconductor element with a mold compound which is substantially transparent to the light emitted by the semiconductor element in such a way that the at least one cavity is at least filled with the mold compound; and
Arranging at least one cover element which is substantially transparent to the light emitted by the semiconductor element in such a way that the at least one cover element is arranged floating on the mold compound as seen in an emission direction of the optoelectronic lighting device.

In some embodiments, the step of arranging the at least one cover element takes place after the step of casting the at least one semiconductor element with the mold compound. The mold compound is in a liquid or at least viscous state at the time the at least one cover element is arranged. On the one hand, this can ensure a sufficiently good connection between the cover element and the mold compound and, on the other hand, by sufficiently introducing the mold compound and subsequently pressing on the cover element, it can be ensured that, depending on the size of the cover element, the mold compound is pressed into areas between the cover element and an upper edge of the frame, for example, so that it is ensured that the cover element is arranged floating on the mold compound.

In some embodiments, the method additionally comprises arranging a reflector or prism on the top surface of the carrier within the at least one cavity, wherein the reflector or prism is configured to deflect the light emitted by the semiconductor element. For example, the reflector or prism can be glued to the top of the carrier and then also encapsulated with the mold compound.

In some embodiments, the step of arranging a frame comprises dispensing a dam material. Accordingly, the frame of an optoelectronic light emitting device may be formed by a dam comprisesing a dam material. In particular, a frame formed by a dam can be characterized by the fact that it can be easily applied to the top of the carrier in almost any shape. Viewed in crosssection, such a dam can, for example, have a round or elliptical shape, a trapezoidal shape or another shape. In particular, such a frame can be formed by beads applied to the carrier.

In some embodiments, however, the step of arranging a frame comprises gluing on a prefabricated frame. The frame may be formed in such a way that it has through-holes which, after the frame has been arranged on the top surface of the carrier, form the at least one cavity together with the carrier. However, it is also possible to apply the frame to the top of the carrier by means of an injection molding process, an injection compression molding process, a compression molding process or a similar process.

Furthermore, several light emitting semiconductor elements can be arranged on the carrier, each in one of several cavities provided by the frame. The cavities or the semiconductor elements may each be molded with the mold compound, and at least a portion of the cover element or a respective separate cover element may be disposed on the mold compound over each of the semiconductor elements. In some embodiments, the method further comprises separating the carrier and/or the frame, and optionally the cover element, to provide one of the at least one optoelectronic light emitting device. The resulting at least one optoelectronic light emitting device may be formed according to some of the aforementioned aspects.

### BRIEF DESCRIPTION OF THE DRAWINGS

In the following, embodiments of the invention are explained in more detail with reference to the accompanying drawings. They show, in each case schematically,

FIG. 1 a sectional view of an unencapsulated optoelectronic lighting device;

FIG. 2 a sectional view of an optoelectronic lighting device encapsulated with a mold compound;

FIG. 3 a sectional view of an optoelectronic lighting device according to some aspects of the proposed principle;

FIG. 4 a sectional view of a further optoelectronic lighting device according to some aspects of the proposed principle;

FIG. 5 a sectional view of a further optoelectronic lighting device according to some aspects of the proposed principle;

FIG. 6 a sectional view of a side-emitting optoelectronic lighting device according to some aspects of the proposed principle; and

FIG. 7 process steps of a process for manufacturing an optoelectronic lighting device according to some aspects of the proposed principle.

### DETAILED DESCRIPTION

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects have a regular structure or shape. It should be noted that slight deviations from the ideal shape may occur in practice without, however, contradicting the inventive concept.

In addition, the individual figures, features and aspects are not necessarily shown in the correct size, and the proportions between the individual elements are not necessarily correct. Some aspects and features are emphasized by enlarging them. However, terms such as “above”, “above”, “below”, “below”, “larger”, “smaller” and the like are shown correctly in relation to the elements in the figures. It is thus possible to deduce such relationships between the elements on the basis of the figures.

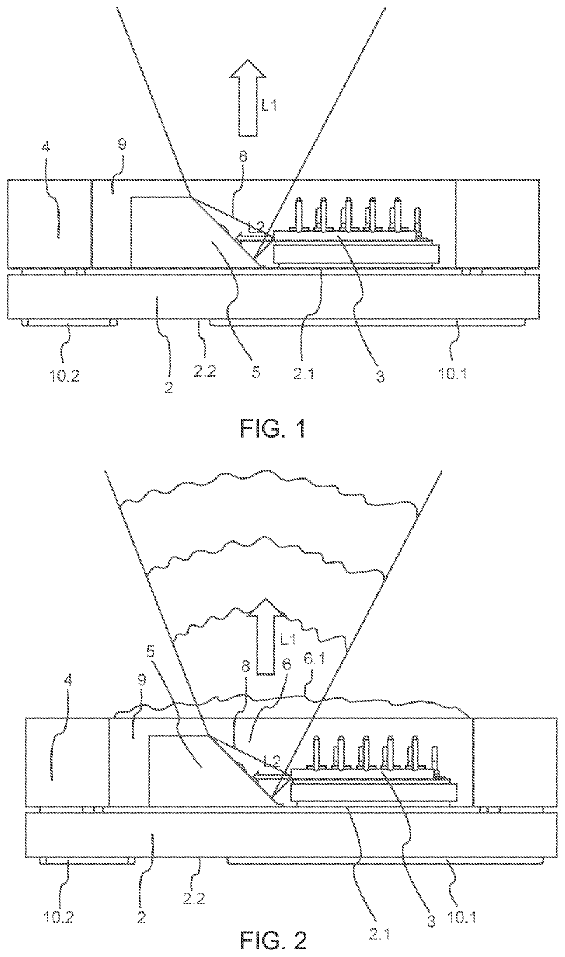

FIG. 1 shows a sectional view of an unencapsulated optoelectronic lighting device. The light emitting device comprises a carrier 2 and a light emitting semiconductor element 3 arranged on a top surface 2.1 of the carrier. The semiconductor element 3 is configured in particular to emit light with a wavelength in the blue and/or ultraviolet range. Furthermore, the lighting device comprises a frame 4, which is arranged on the top surface 2.1 of the carrier and forms a cavity 9 in which the semiconductor element 3 is arranged. A reflector 5 is also arranged in the cavity 9, which deflects the light cone 8 emitted by the semiconductor element 3 in a main emission direction L2 by approximately 90° in the direction of an emission direction L1 of the lighting device. Electrical connection surfaces 10.1, 10.2, via which the lighting device can be supplied with energy and/or controlled, are formed on a bottom surface 2.2 of the carrier 2 opposite the top surface 2.1 of the carrier 2. The lighting device can thus be surface-mounted.

Because the semiconductor element 3 is not encapsulated and is therefore in contact with an environment or oxygen surrounding the optoelectronic lighting device, there is a risk that the semiconductor element 3 will degrade during operation and its performance will therefore decrease over time.

FIG. 2 shows an improved optoelectronic lighting device with regard to the ageing behavior of the semiconductor element 3. The optoelectronic lighting device is encapsulated in a mold compound 6 for this purpose. However, the encapsulation of the light emitting semiconductor element 3 in the mold compound 6 results in an uneven surface on a light exit surface 6.1 of the light emitted by the semiconductor element 3 from the mold compound 6, which has a negative effect on the optical properties/beam quality of the light emitted by the semiconductor element 3. This negative and undesirable influence is characterized in the figure by the wavy lines of the light emerging from the light exit surface 6.1 in the direction of the emission direction L1.

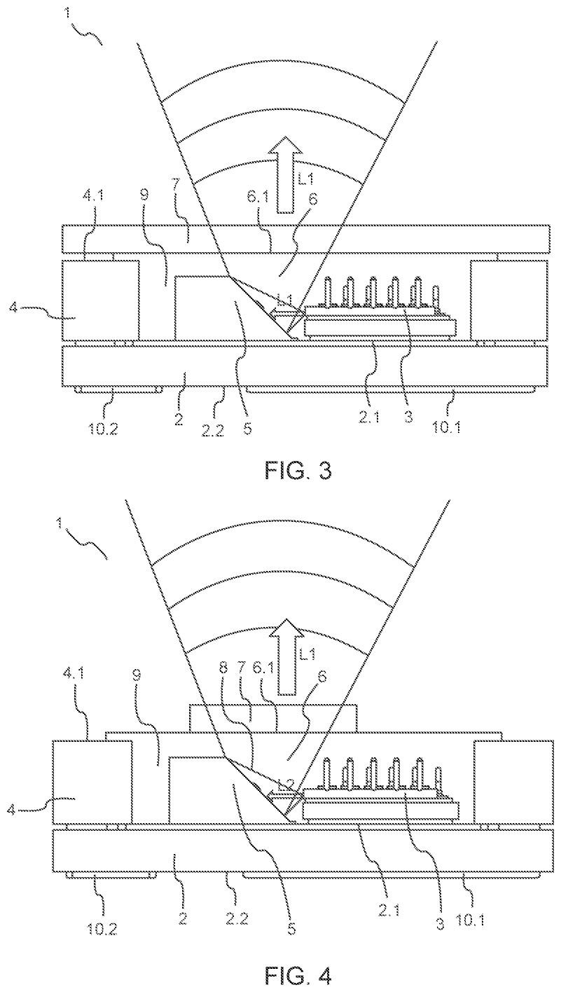

FIGS. 3, 4, 5 and 6 each show a sectional view of an optoelectronic lighting device 1 further improved in this respect according to some aspects of the proposed principle.

For this purpose, a cover element 7 that is substantially transparent to the light emitted by the semiconductor element 3 is arranged on the mold compound 6, at least in the area of the light emission surface 6.1 on the mold compound 6 as viewed in the emission direction L1 of the optoelectronic lighting device 1. The cover element 7 is configured in such a way that the optical properties/the beam quality of the light emitted by the semiconductor element 3 are not or only barely influenced and is arranged on the encapsulation material 6 with a minimum size of the beam diameter of the light emitted by the semiconductor element 3. Contrary to the uneven surface on the mold material shown in FIG. 2, the cover element forms a defined plane that does not negatively influence the phase front of the laser. The improvement in the optical properties/beam quality of the light emitted by the semiconductor element 3 of the optoelectronic lighting devices 1 of FIGS. 3, 4 and 5 compared to the lighting device shown in FIG. 2 is characterized by the smooth propagation lines of the light emerging from the light emitting surface 6.1 in the direction of emission L1. In the embodiments shown, the cover element is designed as a planar plate made of glass or another transparent material. However, it can also be a lens or another beam-shaping element that is placed with a flat side on the mold compound. In some embodiments, the material of the cover plate is selected so that its coefficient of thermal expansion is matched as closely as possible to that of the mold compound. If this is not possible, it is advisable to create a connection that is as stable and intimate as possible in order to prevent premature delamination. However, the design according to the proposed principle already reduces the forces due to different expansion coefficients, as the cover element shown in the figures is free-floating and therefore movable in the axial direction, unlike conventional fixed elements.

As shown in the sectional view in FIG. 3, the cover element 7 can completely cover the cavity 9 and, in particular, side surfaces of the cover element 7 are substantially flush with side surfaces of the frame 4 or side surfaces of the carrier 2. In order to ensure that the cover element 7 is nevertheless arranged floating on the mold compound 6, the cavity 9 is overfilled by means of the mold compound 6, and a part of the mold compound 6 is arranged between an upper edge 4.1 of the frame 4 and the cover element 7. As a result, the cover element 7 is only in contact with the mold compound and is arranged to float on it. In the event of an expansion or general change in volume of the mold compound due to thermal movement, this arrangement nevertheless ensures that the cover element remains floating, i.e. does not come into contact with the edge, thus preventing damage or delamination of the cover element from the mold compound. The flat surface maintains the same phase front of the light.

FIG. 4 shows a further embodiment of an optoelectronic lighting device 1. The cover element 7 is arranged on the mold compound 6 only above the light emission surface 6.1 of the light emitted by the semiconductor element 3 and deflected by the reflector 5. In other words, the area of the cover element is smaller than the area enclosed by the frame, so that the edges of the cover element are also laterally spaced from the frame. A cover element 7 formed in this way can further reduce any stresses that may occur due to heating of the optoelectronic lighting device 1, and costs for the cover element 7 can be saved if it is only limited to an area in which its optical properties are required for improved light extraction.

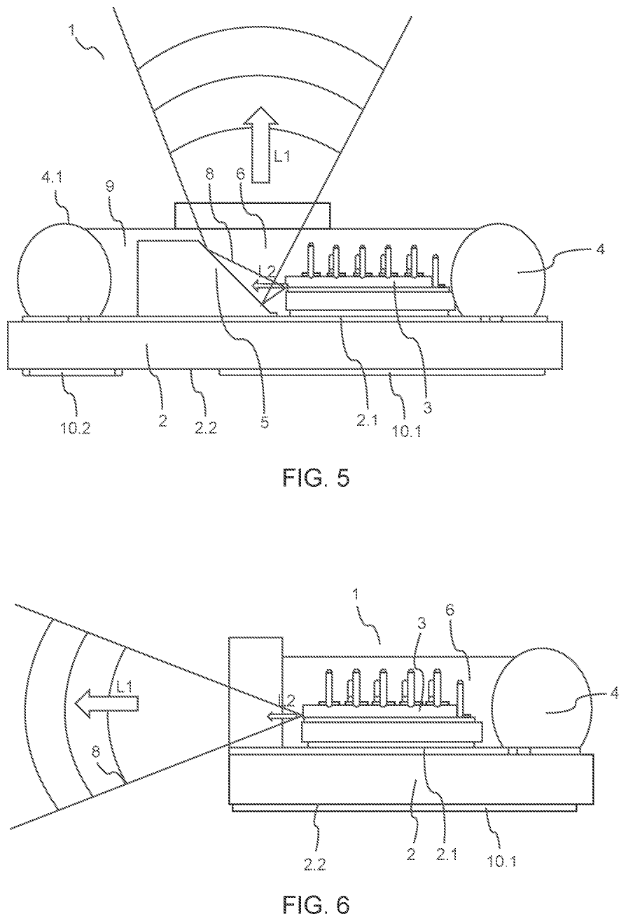

FIG. 5 shows a further embodiment of an optoelectronic lighting device 1. In contrast to the optoelectronic lighting device 1 shown in FIG. 4, the frame 4 is in the form of a dam which, together with the carrier 2, creates the cavity 9. The dam 4 may, for example, have been applied to the top surface 2.1 of the carrier 2 by a dispensing process and, viewed in crosssection, has a cross-sectional shape typical of such a process in the form of a bead arranged on the carrier 2.

Contrary to the preceding embodiments, FIG. 6 shows an optoelectronic lighting device 1 whose emission direction L1 is substantially parallel to the main emission direction L2 of the semiconductor element 3. In the present case, the optoelectronic lighting device 1 accordingly does not have a reflector that deflects the light emitted by the semiconductor element 3. However, it is also conceivable that one or more reflectors are arranged within the cavity and potted in the mold compound 6, which deflect the light emitted by the semiconductor element 3 several times in order to emit it from the optoelectronic lighting device 1 parallel to the main emission direction L2. The optoelectronic lighting device 1 shown is accordingly designed in the form of a side-emitting lighting device 1.

In the present case, the cover element 7 is arranged on the carrier 2 and limits the mold compound 6 on a side opposite the frame 4. The fact that the optoelectronic lighting device 1 is open at the top means that the mold compound 6 can expand in this direction when heated, preventing the cover element 7 from detaching from the support 2. As in the previous embodiment, the frame can be designed in the form of a dam and can be dispensed onto the carrier.

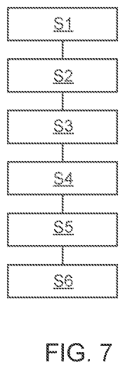

FIG. 7 shows steps of a method for manufacturing an optoelectronic lighting device 1 according to some aspects of the proposed principle.

In a first step S1, at least one light emitting semiconductor element 3, which is configured to emit light with a wavelength smaller than 550 nm, is arranged on a top surface 2.1 of a carrier 2. In a further step S2, at least one reflector 5 or prism is arranged in each case adjacent to the at least one light emitting semiconductor element 3 on the top surface 2.1 of the carrier 2. Subsequently, in a step S3, a frame 4 is arranged on the top surface 2.1 of the carrier 2, the frame 4 together with the carrier 2 forming at least one cavity 9, a light emitting semiconductor element 3 and a reflector 5 or prism being arranged in each of the at least one cavity 9. In a step S4, the at least one semiconductor element 3 and the at least one reflector 5 or prism are then potted with a mold compound 6 which is substantially transparent to the light emitted by the semiconductor element 3, such that the at least one cavity 9 is at least filled with the mold compound 6. In a step S5, at least one cover element 7 which is substantially transparent to the light emitted by the semiconductor element 3 is arranged on the mold compound 6 in such a way that the at least one cover element 7 is arranged floating on the mold compound 6 at least within a light cone 8 emitted by the semiconductor element 3, as viewed in an emission direction L1 of the optoelectronic lighting device 1. In a final step S6, the carrier 2, and in particular the frame 4, and optionally the cover element 7, are separated to provide one of the at least one optoelectronic lighting device 1.

Step S6 can also take place before step S1, so that optoelectronic lighting devices are produced individually and not as a composite. For this purpose, only the carrier 2 is separated in step S6 and the individual components for an optoelectronic lighting device 1 are applied to the separated carrier pieces in the subsequent steps.

What is claimed is:

1. An optoelectronic lighting device comprising:
a carrier;
at least one light emitting semiconductor element arranged on a top surface of the carrier, which is configured to emit light with a wavelength smaller than 550 nm;
a mold compound which is substantially transparent to the light emitted by the semiconductor element and which encapsulates the light emitting semiconductor element on the carrier;
a frame which is arranged on the top surface of the carrier, which projects beyond the light emitting semiconductor element in a direction perpendicular to the top surface of the carrier, and which delimits the mold compound in at least one spatial direction; and
a cover element which is substantially transparent to the light emitted by the semiconductor element and which, viewed in an emission direction of the optoelectronic lighting device, is arranged floating, in particular floating, on the mold compound.

2. The optoelectronic lighting device according to claim 1, wherein the cover element is formed by an optical element, in particular a glass platelet, which preserves the wavefront of the light emitted by the semiconductor element.

3. The optoelectronic lighting device according to claim 1, wherein the mold compound and the cover element comprise a substantially identical refractive index, in particular in the region of an optical interface between the mold compound and the cover element.

4. The optoelectronic lighting device according to claim 1, wherein the cover element has no direct connection to the frame.

5. The optoelectronic lighting device according to claim 1, wherein the light emitting semiconductor element is formed by a side-emitting laser diode.

6. The optoelectronic lighting device according to claim 1, further comprising a reflector or a prism, wherein the reflector or the prism is configured to deflect the light emitted by the semiconductor element.

7. The optoelectronic lighting device according to claim 1, wherein the emission direction of the optoelectronic lighting device is substantially perpendicular to a main emission direction of the semiconductor element.

8. The optoelectronic lighting device according to claim 1, wherein the emission direction of the optoelectronic lighting device and a main emission direction of the semiconductor element are substantially parallel.

9. The optoelectronic lighting device according to claim 1, wherein the frame forms a cavity in which the light emitting semiconductor element is arranged, and wherein the cavity is filled with the mold compound.

10. The optoelectronic lighting device according to claim 9,
wherein the mold compound projects beyond the frame and is arranged at least partially on an upper edge of the frame.

11. The optoelectronic lighting device according to claim 9, wherein in a top view, the cover element completely covers the cavity and in particular at least partially covers the frame.

12. The optoelectronic lighting device according to claim 11, wherein a portion of the mold compound is arranged between the upper edge of the frame and the cover element covering this portion of the frame.

13. The optoelectronic lighting device according to claim 9, wherein in a top view, the cover element comprises a smaller surface area than a surface enclosed by the frame, and wherein in particular the frame is uncovered by the cover element.

14. The optoelectronic lighting device according to claim 1, wherein at least some regions of the mold compound, which are arranged outside a light cone emitted by the optoelectronic lighting device, remain free of the cover element.

15. The optoelectronic lighting device according to claim 1, wherein the mold compound is selected from the group of silicones or siloxanes.

16. The optoelectronic lighting device according to claim 1, wherein a material of the cover element is selected from the group of epoxies or glasses.

17. The optoelectronic lighting device according to claim 1, wherein the cover element is formed by a lens.

18. The optoelectronic lighting device according to claim 1, wherein the optoelectronic lighting device comprises electrical contact surfaces on a side facing away from the top surface of the carrier and is surface-mountable.

19. A method for manufacturing at least one optoelectronic lighting device (1) comprising:
arranging at least one light emitting semiconductor element, which is configured to emit light with a wavelength smaller than 550 nm, on a top surface of a carrier;
arranging a frame on the top surface of the carrier, wherein the frame together with the carrier forms at least one cavity in which the at least one light emitting semiconductor element is arranged;
molding the at least one semiconductor element with a mold compound which is substantially transparent to the light emitted by the semiconductor element in such a way that the at least one cavity is at least filled with the mold compound; and
arranging at least one cover element which is substantially transparent to the light emitted by the semiconductor element in such a way that the at least one cover element is arranged floating on the mold compound as seen in an emission direction of the optoelectronic lighting device.

20. The method according to claim 19,
wherein the step of arranging the at least one cover element is conducted after the step of molding the at least one semiconductor element with the mold compound, and
wherein the mold compound is in a liquid state at the time of arranging the at least one cover element.

21. The method according to claim 19,
further comprising a step of arranging a reflector or prism on the top surface of the carrier within the at least one cavity, wherein the reflector or the prism is configured to deflect the light emitted by the semiconductor element.

22. The method according to claim 19,
wherein the step of arranging a frame comprises dispensing a dam material.

23. The method according to claim 19,
wherein the step of arranging a frame comprises gluing a prefabricated frame.

24. The method according to claim 19, further comprising a step of separating the carrier, and in particular the frame, and optionally the cover element, to provide one of the at least one optoelectronic lighting device.
